(19) United States
(12) Patent Application Publication
(10) Pub. No.: US 2003/0197175 A1
(43) Pub. Date: Oct. 23, 2003

(54) Test structure for evaluating antenna effects

(76) Inventors: Chong-Jen Huang, Taipei Hsien (TW); Kuang-Wen Liu, Nan-Tou Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/063,389

(22) Filed: Apr. 17, 2002

(51) Int. Cl. H01L 23/58

(52) U.S. Cl. 257/48

(57) ABSTRACT

A sensitive test structure for quantitatively detecting antenna effects includes a substrate, an ONO dielectric layer formed over the substrate, an electrode formed over the ONO dielectric layer, and an antenna charge collection electrode (CCE) electrically coupled to the electrode, which is used to collect plasma-induced charge.

### BACKGROUND OF INVENTION

1. Field of the Invention

The present invention relates generally to the field of test wafers for assessing and monitoring plasma potentials over wafers, and more particularly to an NROM-like antenna test structure formed on a test wafer for providing sensitive and quantitative data on plasma-induced charge build-up.

2. Description of the Prior Art

For future integrated circuits, interconnections of tens or hundreds of millions of transistors will have to cope with the complexity of multi-layer interconnections and narrower lines and trenches. The use of high-density plasma seems inevitable, not only to achieve large outputs, but also for the advantages related to anisotropic etching, which is needed to define narrow trenches with straight side walls. For example, reactive-ion-etching (RIE) plasmas are used extensively in many of these processing steps to achieve a high degree of pattern definition and precise dimensional control. Here, the gaseous chemical etching is assisted by radio frequency (RF) plasma. However, it has been shown that plasma processing may also damage the devices being fabricated.

Antenna effects are a typical problem that occurs during semiconductor fabrication, and causes instability of devices when plasma processes are involved. During a plasma process, such as an RIE process, the surface of a semiconductor substrate is bombarded by plasma ions, and a huge number of charged particles, such as electrons, are also created. These charged particles are collected by interconnection surfaces exposed to the plasma and accumulate on devices, resulting in a shifting of the electrical properties of the device, or even in damage to the device, e.g. threshold voltage shifting and gate oxide breakdown.

In general, the strength of antenna effects is proportional to an antenna ratio R, which is typically given by the relation:

R=Aₐ/A_{g}

Where Aₐ is the area of an antenna charge collection electrode (CCE) electrically coupled to a gate, and A_{g} is the area of the gate.

Charge monitor (CHARM) wafers, capable of being reprogrammed and reused, allow process engineers to tune etchers, ashers or ion implanters so that no portion of the wafer is subjected to charging levels greater than the oxide damage threshold. One such CHARM wafer is described in the publication “CHARM wafer characterization”, Reedholm Technical Note TN-1 , June 1996, in which E² PROM cells formed on a wafer according to a preset surface distribution pattern are programmed up to threshold saturation. An E² PROM cell is a flash memory having a floating gate electrode, and a control gate electrode stacked over the floating gate electrode. The floating gate electrode of, for example, polysilicon is separated from a substrate by a thin oxide dielectric film, and the control gate electrode is separated from the floating gate electrode by a thicker dielectric layer.

The E² PROM cells are programmed partly with the maximum positive threshold and partly with the maximum negative threshold. The wafer is then subjected to a treatment, such as a plasma treatment, in order to assess its effects on the wafer. The threshold voltages of the cells are measured and these are compared with the initial maximum threshold voltages. On the basis of the variations in the measured threshold voltages it is possible to get back to the charging potential applied during exposure to the plasma.

However, the prior art CHARM wafer using E² PROM cells has the following drawbacks: the coupling ratio R of the E² PROM cell is insufficient, leading to a reduced sensitivity for plasma detection. The threshold shift Δ V^{t} caused by plasma-induced charge trapped in the floating gate of the E² PROM cell can be defined by the following relation:

Δ Vₜ=(R×Q_{F})/Cₜₒₜₐₗ

Where R is the coupling ratio of the E² PROM cell, Q_{F} is the quantity of charge trapped in the floating gate, and Cₜₒₜₐₗ is the total capacitance of the E² PROM cell. The coupling ratio of an E² PROM cell typically ranges from 0.5 to 0.6. Consequently, the threshold voltage shift is reduced, thus affecting sensitivity for plasma detection. Moreover, E² PROM cells are complex, resulting in a costly CHARM wafer.

Accordingly, there is a need for a more sensitive and cost-saving test structure as well as a plasma test wafer to quantitatively evaluate plasma-induced charge build-up.

### SUMMARY OF INVENTION

In general, in one aspect, the invention is directed to a sensitive test structure for quantitatively detecting antenna effects. The test structure features an ONO dielectric layer. The ONO dielectric layer, which has a bottom oxide layer, a top oxide layer and a nitride layer interposed between the bottom oxide layer and the top oxide layer, is formed over a substrate. An electrode is formed over the ONO dielectric layer. An antenna charge collection electrode (CCE) is electrically coupled to the electrode, and is used to collect plasma-induced charge. Charge induced by plasma are trapped in the silicon nitride layer during a plasma process. According to the present invention, a small quantity of plasma-induced charge can be sensed in terms of a significant threshold voltage shift.

In another aspect, the present invention is directed to a test wafer for evaluating plasma-induced antenna effects. The test wafer comprises a silicon wafer and an array of test structures formed on the silicon wafer. Each test structure comprises a substrate; an ONO dielectric layer formed over the substrate; an electrode formed over the ONO dielectric layer; and an antenna charge collection electrode (CCE) electrically coupled to the electrode used to collect plasma-induced charge.

According to one preferred embodiment of the present invention, the test structure further comprises a source/drain formed in the substrate on either side of the electrode.

According to the present invention, a more sensitive test structure is achieved by utilizing an NROM (nitride read only memory)-like cell architecture having an ONO dielectric layer underneath a gate electrode. Production costs are reduced since manufacturing of ONO test structures is simpler than that for the prior art E² PROM cell.

Other advantages and features of the invention will be apparent from the following description, including the drawings and claims.

### BRIEF DESCRIPTION OF DRAWINGS

The invention can be more fully understood by reading the following detailed description of the preferred embodiments, with reference made to the accompanying drawings as follows:

FIGS. 1 and 2 represent, in plan and in section, an NROM-like test structure unit according to a first preferred embodiment of the present invention.

FIG. 3 is a diagram showing a second preferred embodiment according to the present invention.

### DETAILED DESCRIPTION

As mentioned, one problem arising from the prior art E² PROM-like test structures is that they are fabricated using two layers of polysilicon, i.e. a floating gate and a control gate. Thus, they are more expensive due to the additional lithographic processes, etching processes and excess cleaning processes and so on that are required during the formation of a stacked E² PROM cell structure. Further, measuring and assessing charge built-up across a wafer surface induced by plasma exposure requires the use of more sensitive test structures, which may be formed on special test wafers or designed into regions of the wafer saw kerfs where they are tested by probing prior to dicing. Such test structures are described in the following detailed description.

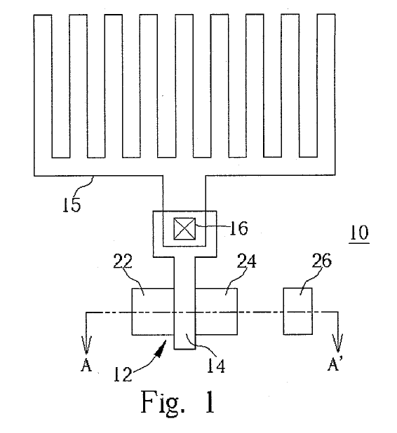

Please refer to FIG. 1. FIG. 1 is an enlarged top view of a test structure according to one preferred embodiment of the present invention. As shown in FIG. 1, a field effect transistor 12 is formed on a substrate 10. The substrate 10 is a wafer of semiconductor material, such as silicon. The transistor 12 includes a gate electrode 14 that is electrically coupled to an antenna structure 15 through a contact plug 16. The gate electrode 14 is made of polysilicon. The antenna structure 15, which may include a single layer interconnection or multi-layer interconnections, collects plasma-induced charge during plasma processing. A source region 22 and a drain region 24 are disposed in the substrate 10 on either side of the gate electrode 14. A pick-up diffusion region 26 is formed in the substrate 10 near the transistor 12.

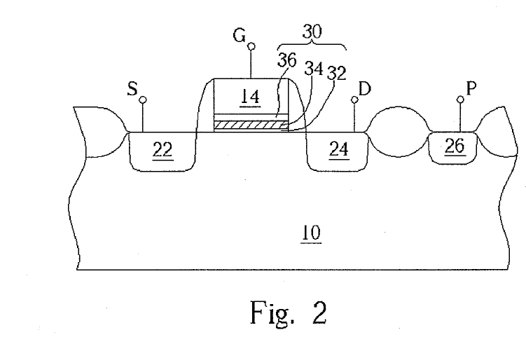

Please refer to FIG. 2. FIG. 2 illustrates a schematic, cross-sectional diagram showing the test structure of FIG. 1 along line AA″. As shown in FIG. 2, the gate electrode 14 is separated from the substrate 10 by an oxide/nitride/oxide (ONO) dielectric layer 30, which consists of a bottom silicon oxide layer 32, a top silicon oxide layer 36, and a silicon nitride layer 34 interposed between the top oxide layer 36 and the bottom oxide layer 32. Source, drain, gate electrode, and pick-up surface metal terminals (pads), indicated as S, D, G and P respectively, are formed on the wafer to constitute electrical contact areas for electrically connecting to external measuring instruments with the source/drain regions, gate electrode, and the pick-up diffusion region.

The ONO dielectric layer 30 may be formed by processes known by those versed in the art. In U.S. Pat. No. 5,966,603, for example, Eitan describes the steps of making an ONO film on a substrate. A bottom oxide layer is first grown over the substrate in a low temperature oxidation operation. A nitride layer is then deposited over the bottom oxide layer by using, for example, chemical vapor deposition techniques. A top oxide is then produced, either through an oxidation of the nitride, by deposition, or by a combination thereof. Preferably, the top oxide layer 36 is about 80 to 100 angstroms thick, more preferably 90 angstroms. The silicon nitride layer 34 is about 60 to 80 angstroms thick, more preferably 70 angstroms. The bottom oxide layer 32 is about 50 to 70 angstroms thick. The definition and formation of the gate electrode 14, and source/drain regions 22 and 24, are fabricated by using conventional lithographic process and dry-etching process, such as a RIE process.

During a plasma operation, plasma-induced charge, such as electrons, are accumulated and collected by the antenna structure 15, causing a charge build-up on one side of the ONO dielectric layer 30 and an energy potential between the substrate 10 and the gate electrode 14. These energized charges are injected into the silicon nitride layer 34 and trapped in the silicon nitride layer 34, thus leading to threshold voltage shift (Δ Vₜ), which can be expressed by the following relation:

Δ Vₜ=Q/C

Where Q is the quantity of charge trapped in the silicon nitride layer 34, and C is the capacitance between the gate electrode 14 and the substrate 10. By measuring the threshold voltage shift Δ Vₜ, the plasma-induced charge trapped in the silicon nitride layer 34 can be quantitatively calculated by multiplying the threshold voltage shift Δ Vₜ by C (Q=Δ Vₜ×C). In comparison with the prior art E² PROM-like test structure, the test structure according to the present invention causes a larger magnitude of threshold voltage shift (Δ Vₜ), since the coupling ratio of the NROM cell is equivalent to 1.

Generally, in a Vₜ measurement operation, the source region 22 and the substrate 10 are grounded. A positive voltage of about 1.6 Volts is applied to the drain region 24. Gradually increasing positive voltages are applied to the gate electrode 14. A threshold voltage shift (Δ Vₜ) is obtained by comparing the measured shifted threshold voltage and a reference threshold voltage. The Vₜ measurement operation is well known by those versed in the art, and a more detailed discussion is thus omitted.

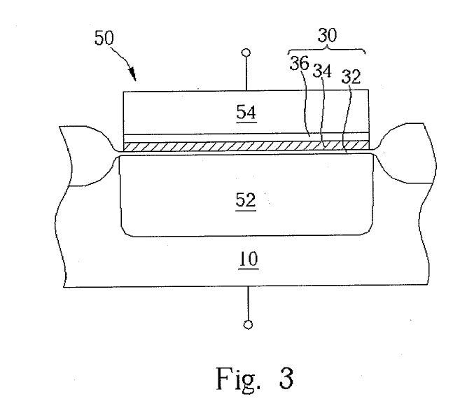

Please refer to FIG. 3. FIG. 3 is a schematic, cross-sectional diagram illustrating a C-V test structure with an ONO dielectric layer according to a second preferred embodiment of the present invention. As shown in FIG. 3, an array of capacitor-type test structures 50 is fabricated on a substrate 10, such as a p-type silicon substrate. The capacitor 50 comprises a top electrode 54 of, for example, polysilicon, or a metal, such as tungsten or silicide. A charge collection electrode (CCE) structure, or an antenna structure (not shown), is electrically coupled to the top electrode 54. A doped well 52, which acts as a bottom electrode of the capacitor 50, is formed in the substrate 10 underneath the top electrode 54. An ONO dielectric layer 30, consisting of a bottom silicon oxide layer 32, a top silicon oxide layer 36, and a silicon nitride layer 34 interposed between the top oxide layer 36 and the bottom oxide layer 32, is formed between the top electrode 54 and the bottom electrode 52. Generally, the test structure 50 occupies a chip size of approximately 100 μm×100 μm. A conventional C-V probing method is used to efficiently measure a threshold shift of the plasma-affected test structures. The C-V probing method involves the use of a probe electrically coupled to the top electrode 54 during a measurement step, while the substrate 10 is grounded. A known “flat-band shift” method is also used to calculate the threshold voltage shift with respect to a reference threshold.

Compared to the prior art E² PROM-like test structure, the present invention provides a more sensitive NROM-like test structure and a capacitor-type test structure having an ONO dielectric layer for assessing plasma-induced charge over a wafer during a plasma operation. A small quantity of plasma-induced charge can be sensitively detected and measured by either a C-V method or by traditional Vₜ measurement steps.

Those skilled in the art will readily observe that numerous modification and alterations of the device may be made while retaining the teachings of the invention. Accordingly, the above disclosure should be construed as limited only by the metes and bounds of the appended claims.

What is claimed is:

1. A test structure for quantitatively detecting antenna effects, the test structure comprising:
a substrate;
an ONO dielectric layer formed over the substrate, wherein the ONO dielectric layer is composed of a bottom oxide layer, a top oxide layer, and a silicon nitride layer interposed between the bottom oxide layer and the top oxide layer;
an electrode formed over the ONO dielectric layer; and
an antenna charge collection electrode (CCE) electrically coupled to the electrode, the antenna CCE being used to collect plasma-induced charge.

2. The test structure according to claim 1 wherein the plasma-induced charge is trapped in the silicon nitride layer.

3. The test structure according to claim 1 wherein the electrode is made of polysilicon.

4. The test structure according to claim 1 wherein the electrode is made of metal.

5. The test structure according to claim 1 wherein the top oxide layer is about 80 to 100 angstroms thick, the silicon nitride layer is about 60 to 80 angstroms thick, and the bottom oxide layer is about 50 to 70 angstroms thick.

6. The test structure according to claim 1 wherein the antenna CCE comprises a single layer interconnection, or multi-layer interconnections.

7. The test structure according to claim 1 further comprising a source/drain formed in the substrate on either side of the electrode.

8. A test wafer for evaluating plasma-induced antenna effects, the test wafer comprising:
a silicon wafer;
an array of NROM-like test structures formed on the silicon wafer, wherein each NROM-like test structure comprises:
a substrate;
an ONO dielectric layer formed over the substrate, the ONO dielectric layer composed of a bottom oxide layer, a top oxide layer and a silicon nitride layer interposed between the bottom oxide layer and the top oxide layer;
an electrode formed over the ONO dielectric layer; and
an antenna charge collection electrode (CCE) electrically coupled to the electrode, the antenna CCE used to collect plasma-induced charge.

9. The test wafer according to claim 8 wherein the plasma-induced charge is trapped in the silicon nitride layer.

10. The test wafer according to claim 8 wherein the electrode is made of polysilicon.

11. The test wafer according to claim 8 wherein the top oxide layer is about 80 to 100 angstroms thick, the silicon nitride layer is about 60 to 80 angstroms thick, and the bottom oxide layer is about 50 to 70 angstroms thick.

12. The test wafer according to claim 8 wherein the NROM-like test structure further comprising a source/drain formed in the substrate on either side of the electrode.
